(19) United States
(12) Patent Application Publication
(10) Pub. No.: US 2025/0008713 A1
(43) Pub. Date: Jan. 2, 2025

(54) SYSTEM AND METHOD FOR REDUCING ELECTROMAGNETIC RADIATION INSIDE A VEHICLE

(71) Applicant: V-HOLA Labs Ltd., Kfar Saba (IL)

(72) Inventors: Benjamin MAY, Lübs (DE); Sven FLECK, Sindelfingen (DE); Asaf TSIN, Kfar Saba (IL)

(73) Assignee: V-HOLA Labs Ltd., Kfar Saba (IL)

(21) Appl. No.: 18/698,616

(22) PCT Filed: Oct. 3, 2022
(86) PCT No.: PCT/IL2022/051049

§ 371 Date: Apr. 4, 2024

Related U.S. Application Data
(60) Provisional application No. 63/252,289, filed on Oct. 5, 2021.

(51) Int. Cl. H05K 9/00; G01R 29/08; H01Q 3/26

(52) U.S. Cl. CPC H05K 9/0071; G01R 29/0814; H01Q 3/2611

(57) ABSTRACT

A method of reducing electromagnetic (EM) radiation inside a vehicle, is disclosed. The method comprises: determining, for at least one location inside the vehicle an existence of at least a first EM radiation vector, and emitting, from at least one emitting element, EM radiation characterized by producing, in the at least one location, at least a second EM vector having an opposite direction to the at least first EM radiation vector.

### CROSS REFERENCE TO RELATED APPLICATIONS

This application claims the benefit of priority of U.S. Provisional Patent Application No. 63/252,289, filed Oct. 5, 2021, the contents of which are all incorporated herein by reference in their entirety.

### FIELD OF THE INVENTION

The present invention relates generally to dealing with electromagnetic (EM) radiation inside a vehicle. More specifically, the present invention relates to system and method of reducing EM radiation inside a vehicle.

### BACKGROUND OF THE INVENTION

Electric vehicles are the transportation means of the future. Electric and hybrid cars are already run in millions on roads all over the world, and electric airplanes and ships are under development. These vehicles include many electronic components that may emit electromagnetic (EM) radiation that may accumulate, for example, in the passengers' cabin. Such radiation, if above a certain level may be harmful, thus should be at least mapped and optionally also dealt with.

Additional EM radiation may be added from external devices/systems, for example, battery charging stations, cellular antennas, and the like.

The harmful level of EM radiation relays on the identity and/or the type of users/passengers having common characterizations. For example, small children (toddlers and babies) are more sensitive than adults. In yet another example, people with heartrate pacers or other medical conditions are more sensitive to EM radiation than healthy people. In addition, the duration of exposure to EM can also affect the level of harmful radiation. The longer the duration the higher is the accumulated amount of EM energy absorbed by the user. Therefore, the level of EM radiation at specific locations (e.g., near the driver's seat in a taxi) must be lower than the allowed EM radiation levels in the back seat. For example, a professional driver (e.g., a taxi driver, a truck driver, etc.) driving for very long hours cannot be exposed to the same EM levels that an occasional passenger can.

The only currently known way to reduce the EM radiation inside a vehicle includes reducing the power and capacity of the emitting components inside the vehicle. However, such a method will affect the performance of the vehicle (e.g., reduce the velocity, reduce the air conditioning, etc.).

Accordingly, there is a need for a system and a method for actively reducing the EM radiation inside the vehicle without the need to reduce the performance of the vehicle.

### SUMMARY OF THE INVENTION

Some aspects of the invention may be related to a method of reducing electromagnetic (EM) radiation inside a vehicle, comprising: determining, for at least one location inside the vehicle an existence of at least a first EM radiation vector; and emitting, from at least one emitting element, EM radiation characterized by producing, in the at least one location, at least a second EM vector having an opposite direction to the at least first EM radiation vector.

In some embodiments, determining further includes determining at least one frequency and at least one corresponding phase of the first EM radiation vector and wherein the second EM radiation vector has similar at least one frequency and an opposite phase to create destructive interference. In some embodiments, the method further includes: identifying a plurality of frequencies in the first EM radiation vector; determining an intensity and a phase for each frequency; assigning a health score for each identified frequency; selecting at least one frequency having a health score higher than a threshold value; and emitting the EM radiation having substantially the same at least one frequency at a corresponding intensity and an opposite phase. In some embodiments, the health score is determined based on a hazardous level of each frequency and the intensity measured for each frequency.

In some embodiments, the first EM vector is a superposition of EM radiation vectors at various frequencies. In some embodiments, the method further includes: creating for each location from a plurality of locations a frequency-dependent histogram of the EM radiation intensities; calculating for each location a representative heat value based on the frequency-dependent histogram and the health score assigned to each frequency; for each location, determining an importance level; and emitting from an array of emitting elements EM radiation that creates destructive interference with the first EM radiation vector at locations having an importance level higher than a threshold. In some embodiments, the method may further include creating a 3D map of the representative heat values of the plurality of locations.

In some embodiments, the method may further include: creating a 3D map of first EM radiation vectors at a plurality of locations; for each location in the map, determining an importance level; and emitting from an array of emitting elements second EM radiation that creates destructive interference with the first EM radiation vector at locations having an importance level higher than a threshold. In some embodiments, the level of importance is determined based on at least one of: an occupancy of the location by a user, an amount of time the user is occupying the location, an age of the user, gender of the user, a height of the user and a weight of the user and the health record/status of the user.

In some embodiments, the occupancy of the location is received from one of: a seat mat, a weighing sensor, a volume sensor (microphone), a motion detector, an image recognition analysis of one or more images taken inside the vehicle (camera), driver monitoring systems, fingerprint systems, and voice recognition system. In some embodiments, the weight of the user is received from one of: a weighing sensor and an estimation made from an image recognition analysis of one or more images taken inside the vehicle. In some embodiments, the age of the user is received from one of: an image recognition analysis of one or more images taken inside the vehicle and an input from a user device.

In some embodiments, determining includes determining the magnetic flux density vector field of the EM radiation over time. In some embodiments, determining the at least first EM vector is from one or more EM radiation sensing units located in proximity to the at least one location. In some embodiments, the one or more EM radiation sensing units and the at least one emitting element are integrated within a child seat. In some embodiments, determining the at least first EM vector is by calculating the EM vector EM radiation from measurements received from a plurality of EM sensing units located at known locations in the vehicle. In some embodiments, determining the at least first EM vector is by calculating the EM vector from information related to EM emitting components of the vehicle and/or of vehicle-related component. In some embodiments, the information comprises, for each emitting component, at least one of: a current, a voltage, a power and a location of the component in or in proximity relative to the vehicle.

In some embodiments, at least one emitting element is located in proximity to each location form the at least one location. In some embodiments, emitting the EM radiation is from an array of emitting elements. In some embodiments, the location of each emitting element in the array is determined such that a sum of EM radiations from all emitting elements minimizes the EM radiation vector field at the at least at one location. In some embodiments, minimizing the EM radiation vector field comprises: determining an importance level for the at least at one location; and minimizing the EM radiation vector field if the at least at one location has a level of importance higher than a threshold.

In some embodiments, the method may further include: receiving maximum allowed EM radiation intensity level; comparing the first EM radiation vector's intensity to the maximum allowed EM radiation intensity level; and emitting the EM radiation if the first EM radiation vector's intensity is equal to or higher than the maximum allowed EM radiation intensity level. In some embodiments, the method may further include: receiving information related to a user, comprising at least one of: an amount of time a user is occupying the location, an age of the user, a height of the user a weight of the user and medical records of user; and modifying the maximum allowed EM radiation intensity level based on the received information.

In some embodiments, the one or more locations are selected from: a driver's seat, front passenger seat, back passenger seat and a child seat.

Some additional aspects of the invention may further be related to an additional method of reducing electromagnetic (EM) radiation inside a vehicle, comprising: receiving from one or more sensing units a first EM radiation at a plurality of locations inside the vehicle; determining representative heat values for at least some of the locations based on the received EM radiation; determining an importance level for the at least some of the plurality of locations; identifying at least one location having an importance level higher than a threshold value; and emitting, from at least one EM emitting unit, a second EM radiation having an opposite direction to the first EM radiation, in the identified at least one location.

In some embodiments, the method may further include, creating a 3D map of the representative heat values. In some embodiments, determining representative heat values comprises: creating for at least some of the locations, a frequency dependent histogram of the EM radiation intensities; assigning a health score for each frequency in the histogram; and calculating for each location a representative heat value based on the intensity of at least some of the frequencies in the histogram and the corresponding health scores. In some embodiments, the health scores are determined based on a hazardous level of each frequency and the intensity measured for each frequency.

In some embodiments, the method may further include: selecting from the identified at least one location a location having the highest level of importance; and emitting the second EM radiation to the selected location. In some embodiments, the method may further include periodically updating the importance level for the at least some of the plurality of locations. In some embodiments, the method may further include continuously updating the importance level for the at least some of the plurality of locations. In some embodiments, updating the importance level is based on at least one of: an occupancy of the location by a user, an amount of time the user is occupying the location, an age of the user, gender of the user, a height of the user and a weight of the user and the health record/status of the user. In some embodiments, the level of importance is determined based on at least one of: an occupancy of the location by a user, an amount of time the user is occupying the location, an age of the user, gender of the user, a height of the user and a weight of the user and the health record/status of the user.

In some embodiments, the occupancy of the location is received from one of: a seat mat, a weighing sensor, a volume sensor (microphone), a motion detector, an image recognition analysis of one or more images taken inside the vehicle (camera), driver monitoring systems, fingerprint systems, and voice recognition system. In some embodiments, the weight of the user is received from one of: a weighing sensor and an estimation made from an image recognition analysis of one or more images taken inside the vehicle. In some embodiments, the age of the user is received from one of: an image recognition analysis of one or more images taken inside the vehicle and an input from a user device.

Some additional aspects of the invention are related to a system for reducing electromagnetic (EM) radiation inside a vehicle, comprising: one or more EM sensing units; one of more EM generating units; and a processor configured to execute any one of method steps disclosed herein above.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram, depicting a computing device which may be included in a system according to some embodiments of the invention;

FIG. 2 is a block diagram, depicting a system reducing EM radiation in a vehicle according to some embodiments of the invention;

FIG. 3 is a flowchart of a method of reducing EM radiation in a vehicle according to some embodiments of the invention;

FIG. 4 is an illustration of a virtual 3D mesh of a passengers' cabin of a vehicle according to some embodiments of the invention;

FIG. 5 is an illustration of a histogram of EM radiation amplitude at various frequencies measured at a location in the vehicle according to some embodiments of the invention;

FIG. 6 is an illustration of a graph showing the EM radiation amplitude along a line (1D map) located between the driver's door to the front passenger door in a vehicle, according to some embodiments of the invention; and

FIG. 7 is flowchart of another method of reducing EM radiation in a vehicle according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

The term set when used herein can include one or more items. Unless explicitly stated, the method embodiments described herein are not constrained to a particular order or sequence. Additionally, some of the described method embodiments or elements thereof can occur or be performed simultaneously, at the same point in time, or concurrently.

Embodiments of the present invention disclose a method and a system for detection and an active reduction of EM radiation in an area of interest a specific location in a vehicle. Such a system may include two main units, a detection unit for detecting/calculating an EM radiation (e.g., an EM vector) at one or more locations inside the vehicle, and an emitting unit for emitting destructive EM radiation to the one or more locations inside the vehicle. In some embodiments, the destructive EM radiation has substantially the same intensity but an opposite direction.

In some embodiments, each location inside the vehicle (e.g., in the passenger cabin) may be labeled with an “importance level”. For example, locations having a high level of importance may include locations which are potentially occupied by a user, such as, a driver's seat, front passenger seat, back passenger seat, and a child seat.

The origin of the EM radiation may be from components included in the vehicle (e.g., an electric or hybrid vehicle). Such components may include, for example, the vehicle's electric motor, the vehicle's battery, the vehicle's electric wires, the vehicle's computer, the vehicle's power inverters, the vehicle's relay switches, the vehicle's radiofrequency (RF) components, autonomous vehicle's processor, integrated or standalone (aftermarket) product, and the like. Additionally, EM components outside the vehicle, but in close proximity to the vehicle, may also contribute to the accumulated EM radiation. For example, charging stations, at which the vehicle parks for charging may also add harmful EM radiation to locations in the passenger cabin.

As used herein, a “vehicle” may be any form of transportation that includes one or more EM radiating components. For example, a vehicle may be, an electric car, a hybrid car, an electric bus, an electric train, an electric ship, an electric airplane, and the like.

As used herein, an “EM radiation” may refer to the entire EM spectrum. More specifically, the EM radiation may refer to several more specific spectrums, for example, ultraviolet (UV) 3-30 PHz, infrared (IR) 300 GHz-3PHz, spectrums included in the radiofrequency (RF) spectrum (3 Hz-300 GHz), such as extremely low frequency (ELF) 3-30 Hz, supper low frequency (SLF) 30-300 Hz, ultra-low frequency (ULF) 300-3 KHz, RF broadcasting bands 3 KHz-300 GHz and the like.

As used herein, a “radiating component” may be any component of the vehicle that radiates EM radiation (at any spectrum). Some examples for radiating components radiating EM radiation at the ELF may include: the vehicle's electric motor, the vehicle's battery, the vehicle's electric wires, at least one of the vehicle's computers (e.g., an HPC architecture of electrical vehicles), the vehicle's power inventers, the vehicle's relay switches and the like. Additional example, for radiating components radiating EM radiation at the wireless RF range, may include, the vehicles' Bluetooth communication device, a GPS antenna, cellular radio module, WiFi radio module and the like.

As used herein, a location inside the vehicle (e.g., an area of interest) may include any area, volume, or place in the vehicle that may be affected by the presence of EM radiation above a certain level. For example, the area of interest may include, the passenger's cabin, a cockpit, at least one of the vehicle's electronic components sensitive to EM radiation (e.g., computers), and the like. An electronic component sensitive to EM radiation is a component to which exposure to EM radiation may affect the component's performance.

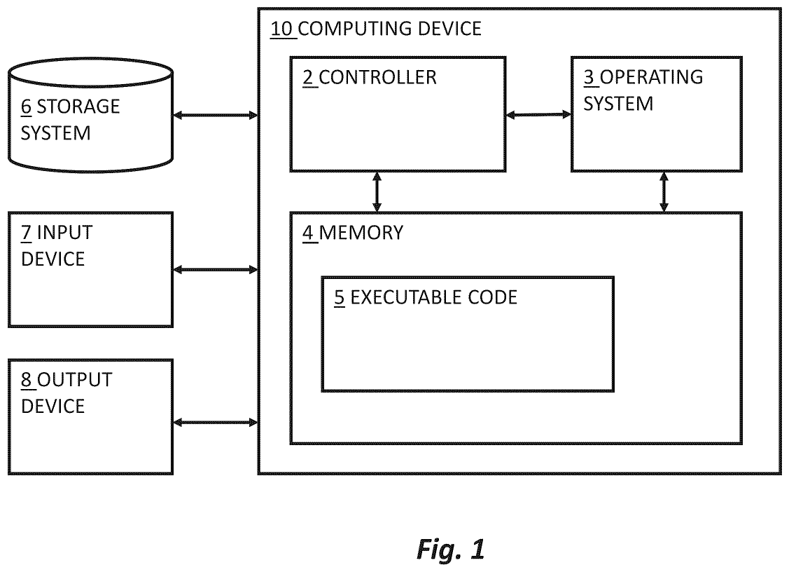

Reference is now made to FIG. 1, which is a block diagram depicting a computing device, which may be included within a system for reducing EM radiation detection and/or reduction inside a vehicle, according to some embodiments. A computing device, such as device 10 may be included in the vehicle's computing system. In some embodiments, more than one computing device 10 may be included in the vehicle's computing system.

Computing device 10 may include a controller 2 that may be, for example, a central processing unit (CPU) processor, a chip or any suitable computing or computational device, an operating system 3, a memory 4, executable code 5, a storage system 6, input devices 7 and output devices 8. Controller 2 (or one or more controllers or processors, possibly across multiple units or devices) may be configured to carry out methods described herein, and/or to execute or act as the various modules, units, etc. More than one computing device 1 may be included in, and one or more computing devices 1 may act as the components of, a system according to embodiments of the invention.

Operating system 3 may be or may include any code segment (e.g., one similar to executable code 5 described herein) designed and/or configured to perform tasks involving coordination, scheduling, arbitration, supervising, controlling, or otherwise managing the operation of computing device 1, for example, scheduling execution of software programs or tasks or enabling software programs or other modules or units to communicate. Operating system 3 may be a commercial operating system. It will be noted that an operating system 3 may be an optional component, e.g., in some embodiments, a system may include a computing device that does not require or include an operating system 3.

Memory 4 may be or may include, for example, a Random Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory units or storage units. Memory 4 may be or may include a plurality of, possibly different memory units. Memory 4 may be a computer or processor non-transitory readable medium, or a computer non-transitory storage medium, e.g., a RAM. In one embodiment, a non-transitory storage medium such as memory 4, a hard disk drive, another storage device, etc. may store instructions or code which when executed by a processor may cause the processor to carry out methods as described herein.

Executable code 5 may be any executable code, e.g., an application, a program, a process, task or script. Executable code 5 may be executed by controller 2 possibly under control of operating system 3. For example, executable code 5 may be an application that may conduct in-vehicle electromagnetic (EM) radiation detection and/or reduction as further described herein. Although, for the sake of clarity, a single item of executable code 5 is shown in FIG. 1, a system according to some embodiments of the invention may include a plurality of executable code segments similar to executable code 5 that may be loaded into memory 4 and cause controller 2 to carry out methods described herein.

Storage system 6 may be or may include, for example, a flash memory as known in the art, a memory that is internal to, or embedded in, a micro controller or chip as known in the art, a hard disk drive, a CD-Recordable (CD-R) drive, a Blu-ray disk (BD), a universal serial bus (USB) device or other suitable removable and/or fixed storage unit. For example, parameters of the vehicle, (virtual) meshing of the vehicle, the location of EM sensing units and/or the locations of radiating components may be stored in storage system 6 and may be loaded from storage system 6 into memory 4 where it may be processed by controller 2. In some embodiments, some of the components shown in FIG. 1 may be omitted. For example, memory 4 may be a non-volatile memory having the storage capacity of storage system 6. Accordingly, although shown as a separate component, storage system 6 may be embedded or included in memory 4. In some embodiments, storage system 6 may be a cloud base storage system.

Input devices 7 may be or may include any suitable input devices, components or systems, e.g., a detachable keyboard or keypad, a mouse and the like. Output devices 8 may include one or more (possibly detachable) displays or monitors, speakers and/or any other suitable output devices. Any applicable input/output (I/O) devices may be connected to Computing device 10 as shown by blocks 7 and 8. For example, a wired or wireless network interface card (NIC), a universal serial bus (USB) device or external hard drive may be included in input devices 7 and/or output devices 8. It will be recognized that any suitable number of input devices 7 and output device 8 may be operatively connected to Computing device 1 as shown by blocks 7 and 8.

A system according to some embodiments of the invention may include components such as, but not limited to, a plurality of central processing units (CPU) or any other suitable multi-purpose or specific processors or controllers (e.g., controllers similar to controller 2), a plurality of input units, a plurality of output units, a plurality of memory units, and a plurality of storage units.

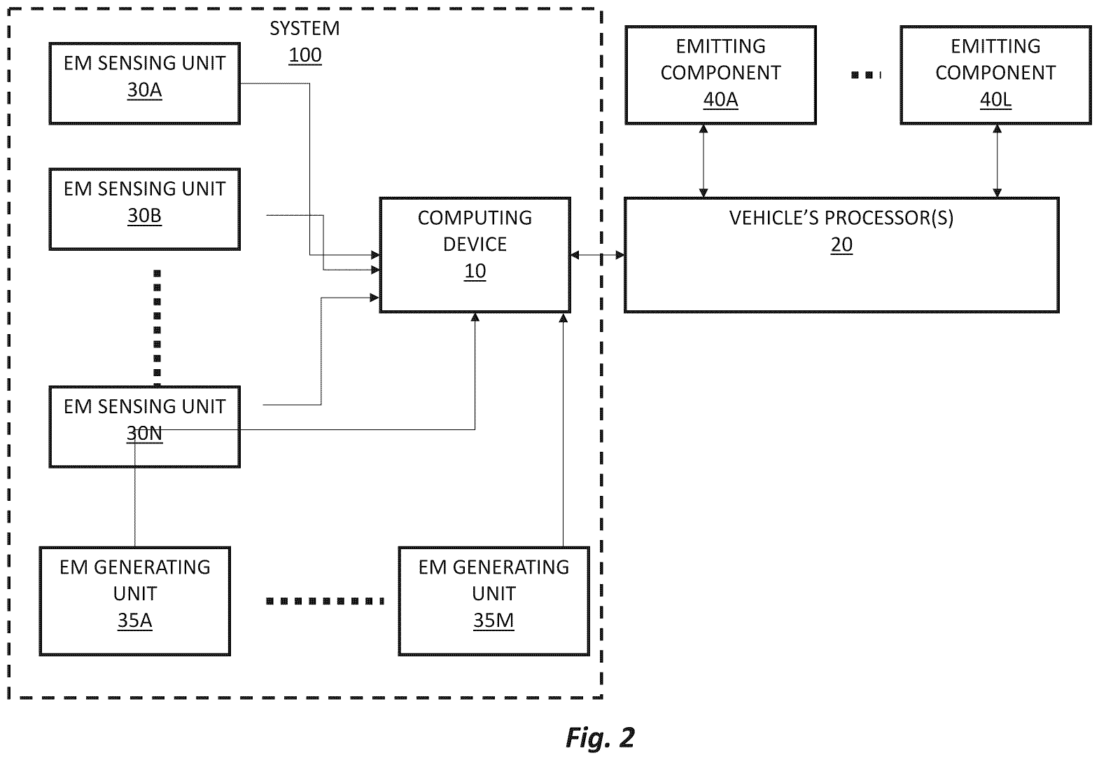

Reference is now made to FIG. 2, which is a block diagram of a system for detection and reduction of in-vehicle EM radiation according to some embodiments of the invention. A system such as a system 100 may include a computing device 10 that may be in communication with one or more of the vehicle's computers 20, for example, via I/O devices 7 and 8. In some embodiments, system 100 may include or may be in communication with one or more EM sensing units 30A-30N and one or more EM generating units 35A-35M. As should be understood by one skilled in the art the three sensing units and the two EM generating units illustrated in FIG. 2 are given as an example only and any number of EM sensing units and EM generating units can be included in the invention. In some embodiments, EM sensing units 30A-30N and EM generating units 35A-35M may communicate with computing device 10 via either wired and/or wireless communication using any known protocol (e.g., LAN, Bluetooth, and the like).

In some embodiments, EM sensing units 30A-30N may include any sensing unit configured to detect an emission vector of an EM field generated by a component of the vehicle (e.g., a first EM radiation vector). In some embodiments, units 30A-30N may each include a single EM sensor configured to measure a 3D EM field (e.g., a magnetic field). In some embodiments, units 30A-30N may each include 3 EM sensors, each configured to measure an EM field (e.g., magnetic field) in a single direction. In such embodiments, the EM sensors may be assembled orthogonal to each other, each configured to measure EM field (e.g., a magnetic field) in a specific direction orthogonal to the direction of the field measured by the two other EM sensors. For example, the sensors may be Anisotropic Magnetoresistive (AMR) Sensors, such as, Honeywell HMC104, available from Honeywell, Hall Effect sensors, such as, DRV5053 available from Texas, Instruments, and the like.

In some embodiments, EM sensing units 30A-30N may be assembled at the closest assembling location to locations having a high level of importance (e.g., higher than a threshold value), and thus may detect the first EM radiation vector at these locations. For example, a sensor 30A may be inserted into a child safety seat, assembled under the driver's seat, at the stirring wheel, etc.

In some embodiments, EM sensing units 30A-30N may be assembled at the closest assembling location to each radiating component. For example, a sensing unit 30A may be assembled on the envelope of the vehicle's electric motor. In another example, a sensing unit 30B may be attached to a wire of the vehicle. In yet another example, a sensing unit 30C may be attached to the Bluetooth device of the vehicle.

In some embodiments, the vehicle may include a plurality of vehicle computers 20, and system 100 may communicate with at least one vehicle computer 20, which may be a computing device, such as computing device 10.

In some embodiments, EM generating unit 35A-35M may include at least one EM generator and one or more EM emitting elements (e.g., antennas) for emitting the generated EM radiation. In some embodiments, a single generator may supply the EM radiation to two or more emitting elements. Alternatively, each one of the EM generating units may include a single EM generator and a single EM emitting unit.

In some embodiments, the EM generator may emit EM at a single frequency, a range of frequencies, and two or more discrete frequencies. For example, an EM generator may be, a solid-state generator (e.g., RF generator), a magnetron and the like. In some embodiments, computing device 10 may control at least one of EM generating units 35A-35M to provide the EM radiation at a specific intensity/amplitude (e.g., power/energy) and a specific frequency. In some embodiments, computing device 10 may control at least one of EM generating units 35A-35M to provide the EM radiation at a specific intensity in two or more frequencies, at a wide/short range of frequencies, and the like. For example, computing device 10 may control EM generating units 35A-35M to generate EM radiation at one or more frequencies in the RF spectrum. In some embodiments, specific EM radiation generators may be used for generating RF at different ranges, for example, at extremely low frequency (ELF) 3-30 Hz, supper low frequency (SLF) 30-300 Hz, ultra-low frequency (ULF) 300-3 KHz, RF broadcasting bands 3 KHz-300 GHz and the like.

In some embodiments, an EM emitting element may include at least one of: antenna, a waveguide, and the like. In some embodiments, the EM emitting element may be configured to direct the generated EM radiation at a predetermined direction. For example, an antenna may be located at a specific location and adjusted to emit the EM at a specific direction, for example, towards a location with high importance level. In some embodiments, the EM emitting element may include an adjustment mechanism (e.g., a motor and a gear) configured to rotate and/or translate the antenna such that the EM radiation is emitted at the predetermined direction (e.g., opposite to the direction of the first EM radiation vector).

In some embodiments, emitting components 40A-40L may be any component of the vehicle that radiates EM radiation (at any spectrum). Some examples of radiating components radiating EM radiation may include: the vehicle's electric motor, the vehicle's battery, the vehicle's electric wires, at least one of the vehicle's computers 20, the vehicle's power inverters, the vehicle's relay switches, the vehicle's audio or multimedia system, a Bluetooth communication device, a GPS antenna, and the like.

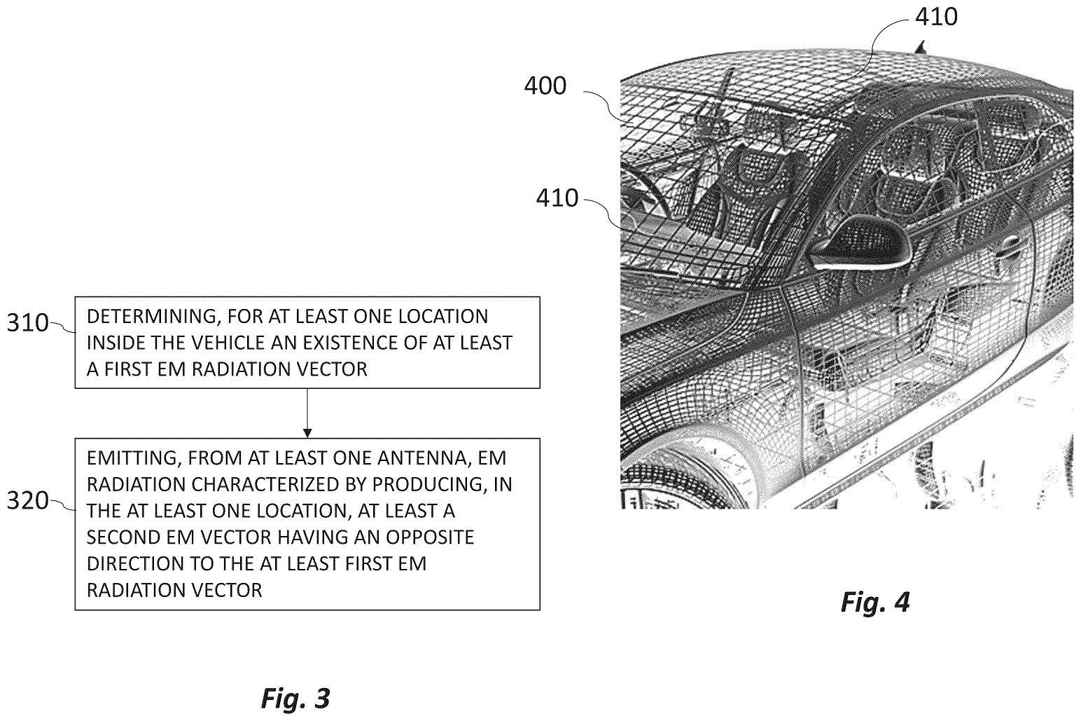

Reference is now made to FIG. 3 which is a flowchart of a method of reducing electromagnetic (EM) radiation inside a vehicle, according to some embodiments of the invention. The method of FIG. 3 may be performed by system 100 under the control/supervision of computing device 10.

In step 310, existence of at least a first EM radiation vector is determined for at least one location inside the vehicle. In some embodiments, the first EM radiation vector may include the magnetic flux density vector field of the EM radiation over time. In some embodiments, the at least first EM vector may be determined from one or more EM radiation sensors located in proximity to the at least one location. For example, at least one EM sensing unit 30A may be placed at the location. In some embodiments, the location may be a location having high importance level. For example, a first EM sensing unit 30A may be located under the driver's seat, a second EM sensing unit 30B may be located under the front passenger seat, a third and fourth EM sensing units 30C and 30D may be located under the passenger back seat and the fifth EM sensing unit 30E may be located inside a child's safety chair. In such a case, a direct measurement of the first EM radiation vector in each location may be conducted. In another example, a sensor, such as for example, but not limited to, sensing element 30A may be located near, the driver's seat, attached to the headrest of the driver seat or attached to the headrest of any of the passengers' seats and the like.

In some embodiments, the level of importance may be determined based on at least one of: occupancy of the location by a user, the amount of time the user is occupying the location, an age of the user, gender of the user, a height of the user and a weight of the user and the health record/status of the user. In some embodiments, the occupancy of the location is received from one of: a seat mat, a weighing sensor, a volume sensor (microphone), a motion detector, an image recognition analysis of one or more images taken inside the vehicle (camera), driver monitoring systems, fingerprint systems, and voice recognition system. In some embodiments, the weight of the user is received from one of: a weighing sensor and an estimation made from an image recognition analysis of one or more images taken inside the vehicle. In some embodiments, the age of the user is received from one of: an image recognition analysis of one or more images taken inside the vehicle and input from a user device. In some embodiments, the age of the user may include detecting an assembling of at least one of: a child seat, a baby safety seat, and a booster seat inside the vehicle and determining the age group of a child/toddler seating in one of these seats based on the type of the seat.

In some embodiments, determining the at least first EM vector is by calculating the EM vector EM radiation from measurements received from a plurality of EM sensing units located at known locations in the vehicle. For example, sensing units 30A-30N may be located in proximity or at least some of the EM emitting components of the vehicle, as discussed herein above, and the at least first EM vector is calculated by vector addition of all EM radiation vectors, measured by sensing units 30A-30N, directed to the at least one location.

In some embodiments, determining the at least first EM vector is by calculating the EM vector EM radiation from measurements received from a plurality of EM sensors located at known locations in the vehicle. In some embodiments, the sensing units may be assembled at the closest assembling location to each radiating component. For example, a sensing unit 30A may be assembled on the envelope of the vehicle's electric motor. In another example, a sensing unit 30B may be attached to a wire of the vehicle. In yet another example, a sensing unit 30C may be attached to the Bluetooth device of the vehicle.

In some embodiments, computing device 10 may calculate the accumulated first EM vector at each location in the vehicle (e.g., having a higher level of importance) using vector addition.

In some embodiments, determining the at least first EM vector is by calculating the EM vector from information related to EM emitting components of the vehicle and/or of vehicle-related components. In some embodiments, the information comprises, for each emitting component, at least one of: a current, a voltage, a power, and a location of the component in or in proximity relative to the vehicle. For example, computing device 10 may receive from one or more vehicles computers 20 operation parameters (e.g., the current flowing in, to, or from an electric component) of at least one emitting component 40A-40M, in real-time. In some embodiments, computing device 10 may be configured to calculate indications related to emission vectors of EM field based on the received operation parameters, for example, by calculating the size and direction of the magnetic field using equation (1):

$$\vec{{B}_{J}} = \frac{{μ}_{0} \vec{ι}}{2 π r} \qquad ( 1 )$$

Wherein, \vec{B} is the EM emission vector (e.g., the magnetic field vector) generated by radiation component j (j=1 to M), i the current flowing in, to, or from an electric component and r the distance from the radiating component.

In some embodiments, receiving the one or more indications may be conducted at predetermined time intervals. For example, one or more indications may be received from sensing units 30A-30N or may be calculated every several seconds, for example, every 0.1, 0.5, 1, 2, 3, or 4 seconds. In some embodiments, the time interval may be determined such that it will not exceed the maximum allowed exposure time according to safety regulations (e.g., 6 minutes). In some embodiments, the longer the time of exposure the higher is the risk for harmful damage (either to a human, an animal, or electronic components). Accordingly, a maximum allowed exposure time is defined by the International Commission on Non-Ionizing Radiation Protection (ICNIRP). World Health Organization (WHO) instructions as well as regulatory bodies worldwide instructions derive from ICNRIP's recommendations. ICNIRP updates its recommendations from time to time.

In some embodiments, a 3D mesh of locations within the vehicle may be received, for example, from the vehicle's manufacturers, for example, mesh 400 illustrated in FIG. 4 or may be calculated based on the vehicle's parameters. In some embodiments, the mesh and/or vehicle's parameters may be stored in a database, for example, storage system 6.

In some embodiments, device 10 may identify in the mesh one or more nodes 410, which are defined as points on the mesh located at the intersection of two or more mesh lines. Each node is located at a specific known location in the vehicle. In some embodiments, the identified mesh nodes may each be located to a location in the vehicle having an importance level higher than a predetermined value, or nodes located at predetermined locations in the vehicle. For example, device 10 may identify only nodes located at locations in the vehicle occupied by the upper body of the driver, locations occupied by a child seating in a child seat, and the like.

In some embodiments, computing device 10 may calculate the distance of each identified node from each sensing unit 30A and/or emitting components 40A-40M. In some embodiments, computing device 10, may use the distance as “r” in equation (1) to calculate the size of the magnetic field generated by each emitting components 40A-40M at a certain node. As can be understood from equation (1) the closer the subject (e.g., human, animal or electric component) to the radiation source the higher is the intensity of the EM field. Since the intensity is proportional to B² the intensity decays in

$$\frac{1}{{r}^{{}_{2}}} .$$

In some embodiments, computing device 10 may adjust the readings received from one or more sensing units 30A-30N based on the distance between each sensing unit and the node using, for example, equation (1). Computing device 10 may receive the distance between a sensing unit and the closest radiating element, and the distance from the radiating element to the node.

In some embodiments, the EM field of at least one node of the 3D mesh may be calculated by vector addition of the emission vectors of the EM fields at the node's location. For example, for at least one node all the magnetic fields vector calculated for each emitting component 40A-40M may be summed, using equation (2).

$$\vec{{B}_{n o d e}} = {\sum }_{M}^{1} {B}_{j} \qquad ( 2 )$$

In some embodiments, computing device 10 may calculate the exposure time T to the radiation levels using equation (3). The Exposure time is defined as the maximum time one is allowed to be exposed to a certain radiation field (e.g., Br) without being harmed.

$$T < \frac{a}{{B}_{n o d e}} \qquad ( 3 )$$

Wherein a is a constant determined based on at least one of: regulation requirements, the subject exposed (e.g., human, animal, electronic equipment, etc.), and the like.

In some embodiments device 10 may form and display (e.g., via output device 8) a 3D map (e.g., heat-map) of the radiation levels at locations having high importance level (e.g., areas of interest). In some embodiments, the 3D maps may be stored in a database, for example, on the cloud based storing service.

Referring, back, to FIG. 3, in step 320, EM radiation may be emitted from at least one EM generating unit (e.g., unit 35A-35M). The emitted EM radiation is characterized by producing, in the at least one location, at least a second EM vector having an opposite direction to the at least first EM radiation vector. For example, computing device 10 may control at least one EM generating unit 35A-35N to emit the second vector, by controlling, the amplitude, direction and/or frequency(ies) of the emitted radiation.

In some embodiments, determining the first EM radiation vector may further include determining at least one frequency and at least one corresponding phase and wherein emitting the second EM radiation vector is at a similar at least one frequency and an opposite phase to create destructive interference.

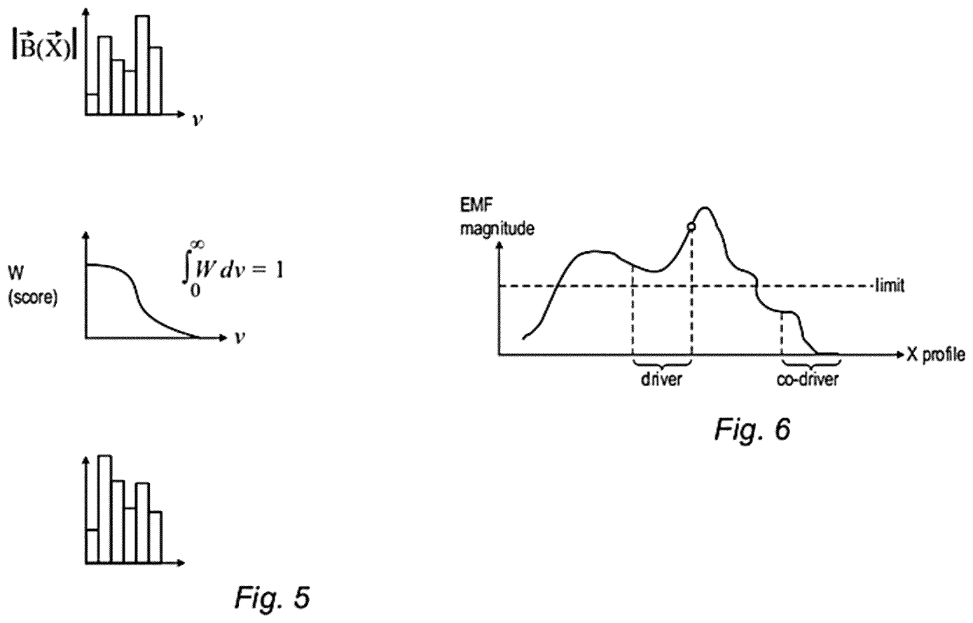

In some embodiments, the method may include, for an identified location (e.g., a node located at a high importance location) identifying a plurality of frequencies in the first EM radiation vector and determining an intensity/amplitude and a phase for each frequency, for example, as illustrated in FIG. 5. FIG. 5 is an illustration of a histogram of EM radiation amplitude at various frequencies measured at a location in the vehicle according to some embodiments of the invention. As shown in FIG. 5, at a specific location, the EM radiation vector may include a superposition of EM radiation vectors having different frequencies and corresponding amplitudes. In some embodiments, each of the frequencies (e.g., in the histogram) may be assigned with a health score. The health score may be determined based on the hazardous level of each frequency and the intensity measured for each frequency. For example, ELF and SLF frequencies were found to have a negative impact on humans. Therefore, computing device 10 may identify these specific frequencies in the determined first vector and the corresponding amplitude of each frequency. For example, computing device 10 may give different weights for frequencies in the hazardous ranges in comparison to frequencies in harmless ranges and multiply the weight with a normalized amplitude (e.g., normalized to the maximal amplitude) to calculate the health score.

In some embodiments, the method includes selecting at least one frequency having a health score higher than a threshold value. For example, computing device 10 may select only the frequency having the highest health score or frequencies having the 4 highest health scores. In some embodiments, the method may include emitting the EM radiation having substantially the same at least one frequency at a corresponding intensity and an opposite phase. For example, the second EM vector may be emitted at the frequency having the highest health score, at substantially the same amplitude, but at the opposite direction and phase, as to form a destructive interference between the first and second EM vector at the selected frequency.

In some embodiments, the method may include creating for each location from a plurality of locations a frequency-dependent histogram of the EM radiation intensities. For example, for each node (e.g., a located at a high importance location) computing device 10 may create a histogram, such as, the histogram of FIG. 5. In some embodiments, computing device 10 may calculate for each location a representative heat value based on the frequency-dependent histogram and the health score assigned to each frequency. For example, the heat value may be the highest health score in each histogram, an average health score in each histogram, a superposition/average of all health scores above a threshold value and the like. In some embodiments, computing device 10 may create a 3D map of the representative heat values of the plurality of locations.

In some embodiments, the method may further include for each location, determining an importance level and emitting from an array of EM generating units EM radiation that creates destructive interferences with the first EM radiation vectors at locations having an importance level higher than a threshold. For example, any array of EM generating units 35A-35M may emit EM radiation to each determined location at specifically selected frequencies having the highest health scores, at corresponding amplitudes and opposite phases and directions.

In some embodiments, the location of each emitting element in the array is determined such that a sum of EM radiations from all EM generating units minimizes the EM radiation vector field at the at least at one location. In some embodiments, minimizing the EM radiation vector field may include, determining an importance level for the at least at one location (as discussed herein above) and minimizing the EM radiation vector field if the at least at one location has a level of importance higher than a threshold.

In some embodiments, the method may further include receiving a maximum allowed EM radiation intensity level (for example, from a health organization/standard), comparing the first EM radiation vector's intensity to the maximum allowed EM radiation intensity level; and emitting the EM radiation if the first EM radiation vector's intensity is equal to or higher than the maximum allowed EM radiation intensity level.

In some embodiments, the method may further include receiving information related to a user, comprising at least one of: an amount of time a user is occupying the location, an age of the user, a height of the user a weight of the user and medical records of user; and modifying the maximum allowed EM radiation intensity level based on the received information. For example, if a standard for maximum allowed EM radiation intensity level was determined for an adult weighing 70 Kg, the maximum allowed level may be reduced for a child weighing 25 Kg, increased for an adult weighing 100 Kg, decreased for adult weighing 70 Kg working as a taxi driver, and the like.

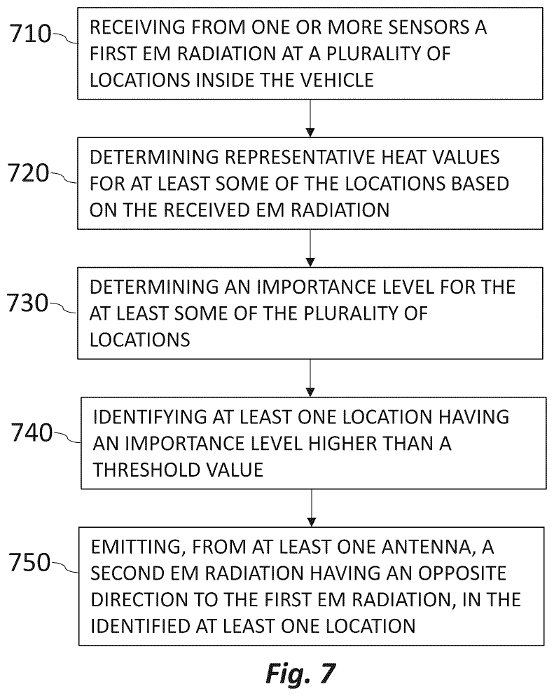

Reference is now made to FIG. 7 which is another method of reducing electromagnetic (EM) radiation inside a vehicle according to some embodiments of the invention. The method of FIG. 7 may be performed by system 100 under the control/supervision of computing device 10.

In step 710, a first EM radiation at a plurality of locations inside the vehicle may be received and/or calculated. For example, the EM from one or more sensing units. For example, computing device 10 may be received from sensing units 30A-30N readings, as disclosed with respect to step 310 of FIG. 3. In yet another example, computing device 10 may calculate the first EM radiation based on information related to at least some of the emitting components of the vehicle, as disclosed herein above. In some embodiments, the received EM radiation may include a histogram of EM radiation amplitude at various frequencies measured at a location in the vehicle, as illustrated and discussed with respect to FIG. 5.

In step 720, representative heat values may be determined, for at least some of the locations based on the received EM radiation. For example, computing device 10 may use the frequency-dependent histogram of the EM radiation intensities for calculating the heat value. In some embodiments, for each node (e.g., a located at a high importance location) computing device 10 may create a histogram, such as, the histogram of FIG. 5. In some embodiments, computing device 10 may calculate for each location a representative heat value based on the frequency-dependent histogram and the health score assigned to each frequency, as discussed herein above. In some embodiments, the heat value may be the highest health score in each histogram, an average health score in each histogram, a super position/average of all health scores above a threshold value and the like. In some embodiments, computing device 10 may create a 3D map of the representative heat values importance level of the plurality of locations.

In some embodiments, computing device 10 may create a 3D map of the representative heat values for at least some of the locations (nodes) inside the vehicle.

In step 730, an importance level may be determined, for the at least some of the plurality of locations. For example, computing device 10 may determine the level of importance based on at least one of: occupancy of the location by a user, an amount of time the user is occupying the location, an age of the user, gender of the user, a height of the user and a weight of the user and the health record/status of the user, as discussed herein above.

In step 740, at least one location having an importance level higher than a threshold value may be identified. For example, computing device 10 may identify if a child is seating a child seat, therefore, marking the location of the child seat as having the highest level of importance. In another example, both the child seat and the driver's seat may be given an importance level higher than the threshold value and computing device 10 may identify both locations. In yet another example, a passenger having a severe medical condition (e.g., a cancer) may be seating in the front passenger seat, raising the level of importance of this location to be above the threshold value. In some embodiments, computing device 10 may give a score/weight for each location in the vehicle, and may update the score based on at least one of an occupancy of the location by a user, an amount of time the user is occupying the location, an age of the user, gender of the user, a height of the user and a weight of the user and the health record/status of the user.

In some embodiments, the method may include periodically updating the importance level for the at least some of the plurality of locations. For example, the importance level may be updated every day, based on data collected by computing device 10 during that day for at least some of the sensors associated with computing device 10. The sensors may provide information related to the weight of the user that occupied a location in the vehicle, the total duration of the occupation, the continuity of the occupation and the like.

In some embodiments, the method may include continuously updating the importance level for the at least some of the plurality of locations. For example, computing device 10 may reactive, in real-time, reading from at least some of the sensors associated with computing device 10 and may update the level of importance accordingly. Computing device 10 may receive an information that a child has been seated in a booster seat, therefore may assign the highest level of importance to this location. Upon detecting that the child is no longer seating in the booster and left the vehicle, computing device 10 may reduce dramatically the level of importance of this location.

In step 750, a second EM radiation having an opposite direction to the first EM radiation may be emitted from one or more emitting elements (included in EM generating units), to the identified at least one location. In some embodiments, computing device 10 may control one or more generating units 35A-35M to emit the second EM radiation to the identified at least one location.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. A method of reducing electromagnetic (EM) radiation inside a vehicle, comprising:
determining, for at least one location inside the vehicle an existence of at least a first EM radiation vector; and
emitting, from at least one emitting element, EM radiation characterized by producing, in the at least one location, at least a second EM vector having an opposite direction to the at least first EM radiation vector.

2. The method of claim 1, wherein determining further includes determining at least one frequency and at least one corresponding phase of the first EM radiation vector and wherein the second EM radiation vector has similar at least one frequency and an opposite phase to create destructive interference.

3. The method of claim 2 comprising:
identifying a plurality of frequencies in the first EM radiation vector;
determining an intensity and a phase for each frequency;
assigning a health score for each identified frequency;
selecting at least one frequency having a health score higher than a threshold value; and
emitting the EM radiation having substantially the same at least one frequency at a corresponding intensity and an opposite phase.

4. The method of claim 3, wherein the health score is determined based on a hazardous level of each frequency and the intensity measured for each frequency.

5. (canceled)

6. The method of claim 3, further comprising:
creating for each location from a plurality of locations a frequency dependent histogram of the EM radiation intensities;
calculating for each location a representative heat value based on the frequency dependent histogram and the health score assigned to each frequency;
for each location, determining an importance level; and
emitting from an array of emitting elements EM radiation that creates destructive interference with the first EM radiation vector at locations having an importance level higher than a threshold.

7. The method of claim 6, further comprising:
creating a 3D map of the representative heat values of the plurality of locations.

8. The method of claim 1, further comprising:
creating a 3D map of first EM radiation vectors at a plurality of locations;
for each location in the map, determining an importance level; and
emitting from an array of emitting elements second EM radiation that creates destructive interference with the first EM radiation vector at locations having an importance level higher than a threshold.

9.-12. (canceled)

13. The method of claim 1, wherein determining includes determining the magnetic flux density vector field of the EM radiation over time.

14. The method of claim 1, wherein determining the at least first EM vector is from one or more EM radiation sensing units located in proximity to the at least one location.

15. (canceled)

16. The method of claim 1, wherein determining the at least first EM vector is by calculating the EM vector EM radiation from measurements received from a plurality of EM sensing units located at known locations in the vehicle.

17. The method of claim 1, wherein determining the at least first EM vector is by calculating the EM vector from information related to EM emitting components of the vehicle and/or of vehicle-related component.

18. The method of claim 17, wherein the information comprises, for each emitting component, at least one of: a current, a voltage, a power, and a location of the component in or in proximity relative to the vehicle.

19. The method of claim 1, wherein at least one emitting element is located in proximity to each location form the at least one location.

20. The method of claim 1, wherein emitting the EM radiation is from an array of emitting elements.

21. The method of claim 20, wherein the location of each emitting element in the array is determined such that a sum of EM radiations from all emitting elements minimizes the EM radiation vector field at the at least at one location.

22. The method of claim 21, wherein minimizing the EM radiation vector field comprises:
determining an importance level for the at least at one location;
minimizing the EM radiation vector field if the at least at one location has a level of importance higher than a threshold.

23. The method of claim 1, further comprising:
receiving maximum allowed EM radiation intensity level;
comparing the first EM radiation vector's intensity to the maximum allowed EM radiation intensity level; and
emitting the EM radiation if the first EM radiation vector's intensity is equal to or higher than the maximum allowed EM radiation intensity level.

24. (canceled)

25. (canceled)

26. A method of reducing electromagnetic (EM) radiation inside a vehicle, comprising:
receiving from one or more sensing units a first EM radiation at a plurality of locations inside the vehicle;
determining representative heat values for at least some of the locations based on the received EM radiation;
determining an importance level for the at least some of the plurality of locations;
identifying at least one location having an importance level higher than a threshold value; and
emitting, from at least one EM emitting unit, a second EM radiation having an opposite direction to the first EM radiation, in the identified at least one location.

27. The method of claim 26, further comprising creating a 3D map of the representative heat values.

28.-37. (canceled)

38. A system for reducing electromagnetic (EM) radiation inside a vehicle, comprising:
one or more EM sensing units;
one of more EM generating units; and
a processor configured to;
receive from the one or more sensing units a first EM radiation at a plurality of locations inside the vehicle;
determine representative heat values for at least some of the locations based on the received EM radiation;
determine an importance level for the at least some of the plurality of locations;
identify at least one location having an importance level higher than a threshold value; and
emitting, from the one or more EM emitting units, a second EM radiation having an opposite direction to the first EM radiation, in the identified at least one location.
